(19) United States
(12) Patent Application Publication
(10) Pub. No.: US 2026/0107471 A1
(43) Pub. Date: Apr. 16, 2026

(54) CORRUGATED SIDEWALL STRUCTURE FOR MEMORY DEVICE

(71) Applicant: Micron Technology, Inc., Boise, ID (US)

(72) Inventors: Jun Ho LEE, Meridian, ID (US); Byung Yoon KIM, Boise, ID (US); Kwangho AHN, Santa Clara, CA (US)

(21) Appl. No.: 19/305,064

(22) Filed: Aug. 20, 2025

Related U.S. Application Data
(60) Provisional application No. 63/708,149, filed on Oct. 16, 2024.

(51) Int. Cl. H10B 53/40; G11C 5/06; H10B 12/00; H10B 53/10; H10D 62/83; H10D 62/85

(52) U.S. Cl. CPC H10B 53/40; G11C 5/063; H10B 12/05; H10B 12/488; H10B 12/50; H10B 53/10; H10D 62/83; H10D 62/8503

(57) ABSTRACT

Implementations described herein relate to various structures, integrated assemblies, and memory devices. In some implementations, an integrated assembly includes an array of semiconductive fin structures penetrating through a dielectric region. The integrated assembly includes a semiconductive moat structure along the dielectric region that includes a sidewall structure The sidewall structure includes first segments that are biased inwardly toward the array of semiconductive fin structures and second segments that are biased outwardly away from the array of semiconductive fin structures, where the first segments and second segments alternate along an edge of the dielectric region to form a crenellated profile along a surface of the sidewall structure that faces the dielectric region. The integrated assembly includes an array of conductive line structures that extend across the array of semiconductive fin structures, across the dielectric region, and across the sidewall structure.

### CROSS-REFERENCE TO RELATED APPLICATION

This patent application claims priority to U.S. Provisional Patent Application No. 63/708,149, filed on Oct. 16, 2024, entitled “CORRUGATED SIDEWALL STRUCTURE FOR MEMORY DEVICE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to a corrugated sidewall structure for a memory device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIG. 2 includes diagrams illustrating views of an example implementation of a portion of a memory array described herein.

FIG. 3 is a flowchart of an example method of forming an integrated assembly or memory device having a corrugated sidewall structure described herein.

FIGS. 4A through 4E are diagrammatic views showing formation of a corrugated sidewall structure at stages of an example process of forming the corrugated sidewall structure.

FIG. 5 is a diagrammatic view of an example memory device.

### DETAILED DESCRIPTION

A memory array of a semiconductor device may include an array of active areas surrounded by a moat structure. The moat structure (a guard ring) may be electrically coupled with the active areas and provide a reference voltage to the active areas. Furthermore, the moat structure may provide benefits to the memory array through noise isolation, leakage current reduction, and/or substrate biasing and isolation.

In some cases, an array of word lines may be formed across the memory array, including across the active areas and a sidewall of the moat structure. Different etch rates resultant from different widths of the active areas and the sidewall may lead to a substantial imbalance in heights of the active areas and the sidewall, which may lead to defects (e.g., open line failures) of word lines during formation of the word lines across the sidewall. Efforts to align the etch rates of the active areas and the sidewall may include forming the active areas and the sidewall to have a substantially similar width. However, miniaturization of the active areas may cause a width of the sidewall structure to be reduced to a point that a structural integrity of the sidewall (and/or the moat structure) is compromised, exposing the sidewall to collapsing and/or toppling under stresses induced by subsequent manufacturing steps.

Some implementations described herein provide a memory array having a moat structure that surrounds an array of active areas and methods of formation. The moat structure includes a corrugated sidewall structure, made of segments that alternate between being biased inwardly and outwardly. Each segment may have a width that enables the corrugated sidewall structure to be etched at a rate similar to that of the active areas. Etching the active areas structures and the corrugated sidewall structure at a similar rate may form trenches having substantially uniform depths, thereby reducing a risk of open line failures during subsequent formation of word lines in the trenches across the active areas and the corrugated sidewall structure. Furthermore, the corrugated sidewall structure includes a crenellated profile, which significantly strengthens structural integrity of the sidewall structure during the etching process and subsequent fabrication stages.

By mitigating the risk of open line failures and increasing a structural integrity of the moat structure, a quality and/or a reliability of a semiconductor device including the memory array may be increased. Such an increase improves technical and resource efficiency objectives by reducing the amount of resources (e.g., raw materials, labor, semiconductor manufacturing equipment, and/or computing resources) needed to support the market consuming the semiconductor device.

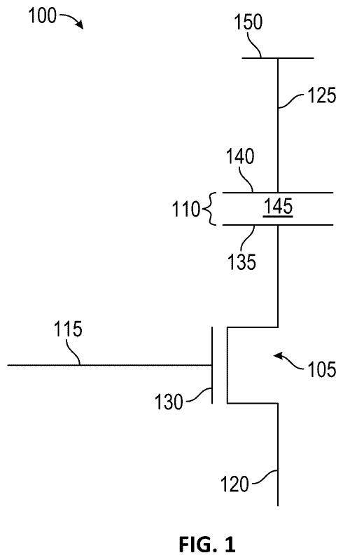

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

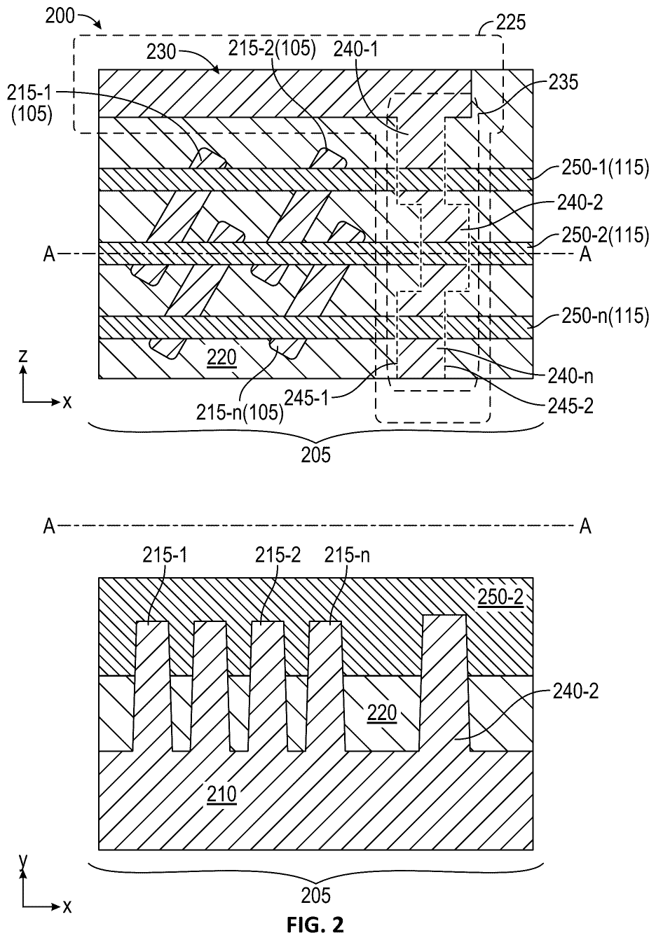

As described in greater detail in connection with FIGS. 2-5, and in some implementations, the memory cell 100 may be one or multiple memory cells formed using array of active areas surrounded by a moat structure. The transistor 105 may be a portion of an active area, and the access line 115 may extend across the active area and over a corrugated sidewall of the moat structure.

As indicated above, FIG. 1 is provided as an example. Other examples may differ from what is described with respect to FIG. 1.

FIG. 2 includes diagrams illustrating views of an example implementation 200 of a portion of a memory array 205 described herein. The diagrams include a plan view (e.g., an x-z view) and a side view (e.g., an x-y view) of the memory array 205. The side view may correspond to a section view along the section line A-A.

As shown in FIG. 2, the memory array 205 includes a semiconductive base 210 and an array of active areas 215-1 through 215-n. In some implementations, and as shown in FIG. 2, the array of active areas 215-1 through 215-n may be fin structures that extend from the semiconductive base 210. The semiconductive base 210 and the array of active areas 215-1 through 215-n may include a semiconductive material that comprises, consists of, or consists essentially of silicon (e.g., polycrystalline silicon), among other examples. Alternatively, the semiconductive material may comprise, consist of, or consist essentially of a type III-V element (e.g., boron, aluminum, phosphorous, gallium arsenide, or gallium nitride, among other examples). In some implementations, each active area of the array of active areas 215-1 through 215-n may correspond to a respective channel of a transistor of a memory cell formed using the memory array 205 (e.g., a channel of a respective transistor 105 of a memory cell 100).

As shown in FIG. 2, a dielectric region 220 may surround the array of active areas 215-1 through 215-n. Additionally, or alternatively, the array of active areas 215-1 through 215-n may penetrate through the dielectric region 220. The dielectric region 220 may be an electrical insulator and may comprise, consist of, or consist essentially of insulative material. The insulative material may comprise, consist of, or consist essentially of silicon dioxide and/or silicon nitride, among other examples.

As further shown in FIG. 2, a moat structure 225 may be along and/or surround the dielectric region 220 and/or the array of active areas 215-1 through 215-n. The moat structure 225 may extend from the semiconductive base 210 and include a semiconductive material as described above. In FIG. 2, a portion (e.g., a corner of the moat structure 225) is illustrated for simplicity.

The moat structure 225 may include an approximately linear sidewall structure 230 that extends along a direction corresponding to the x-axis. The moat structure 225 may further include a corrugated sidewall structure 235 that extends along a direction corresponding to the z-axis. In some implementations, the approximately linear sidewall structure 230 may join with (e.g., merge with) the corrugated sidewall structure 235.

The corrugated sidewall structure may include a series of segments 240-1 through 240-n, where one or more first segments that are biased inwardly toward the array of active areas 215-1 through 215-n alternate with one or more second segments that are biased outwardly away from the array of active areas 215-1 through 215-n. Such a biasing may cause the corrugated sidewall structure 235 to have a crenellated profile 245-1 (e.g., a first crenellated profile including a first series of approximately right angles) along a surface facing the array of active areas 215-1 through 215-n. Additionally, or alternatively, such a biasing may cause the corrugated sidewall structure 235 to have a crenellated profile 245-2 (e.g., a second crenellated profile including a second series of approximately right angles) along a surface facing away from the array of active areas 215-1 through 215-n. In some implementations, the crenellated profiles 245-1 and 245-2 run approximately parallel to one another.

As shown in FIG. 2, the dielectric region 220 may include surfaces that conjoin with surfaces of the array of active areas 215-1 through 215-n. Additionally, or alternatively, surfaces of the dielectric region 220 may conjoin with surfaces of the corrugated sidewall structure 235 (e.g., surfaces along the crenellated profile 245-1 and/or the crenellated profile 245-2).

The corrugated sidewall structure 235 may include surfaces having profiles other than the crenellated profile 245-1 and/or the crenellated profile 245-1. For example, and in some implementations, a surface of the corrugated sidewall structure 235 that faces the array of active areas 215-1 through 215-n may have series of curvatures, causing the surface to have a serpentine profile. Additionally, or alternatively, a surface of the corrugated sidewall structure 235 that faces away from the array of active areas 215-1 through 215-n may have a series of curvatures, causing the surface to have a serpentine profile. Additionally, or alternatively, the corrugated sidewall structure 235 may include opposing surfaces having serpentine profiles that are approximately parallel to each other.

In some implementations, a surface of the corrugated sidewall structure 235 that faces the array of active areas 215-1 through 215-n may include a series of angles other than approximately right angles that form a crenellated profile, causing the surface to have a zig-zag (e.g., a “sawtooth”) profile. Additionally, or alternatively, a surface of the corrugated sidewall structure faces away from the array of active areas 215-1 through 215-n may include a series of angles other than approximately right angles that form a crenellated profile, causing the surface to have a zig-zag profile. Additionally, or alternatively, the corrugated sidewall structure 235 may include opposing surfaces having zig-zag profiles that are approximately parallel to each other.

The moat structure 225, including the approximately linear sidewall structure 230 and the corrugated sidewall structure 235, may electrically couple with the array of active areas 215-1 through 215-n through the semiconductive base 210. By electrically coupling with the array of active areas 215-1 through 215-n, the moat structure 225 may be part of an electrical circuit that provides a reference voltage to the array of active areas 215-1 through 215-n.

As further shown in FIG. 2, the memory array 205 includes an array of conductive line structures 250-1 thorough 245-n that extend along a direction corresponding to the x-axis, where the x-axis is approximately orthogonal to the z-axis. The array of conductive line structures 250-1 through 250-n extends across the array of active areas 215-1 through 215-n, and across the corrugated sidewall structure 235. The array of conductive line structures 250-1 through 250-n may include a conductive material that is an electrical conductor. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. In some implementations, each conductive line of the array of conductive structures 250-1 through 250-n may correspond to an access line (e.g., a word line) for a memory cell formed using the memory array 205 (e.g., an access line 115 of a memory cell 100).

One or more of the array of conductive line structures 250-1 through 250-n (e.g., the conductive line structure 250-2 as shown in the side view of FIG. 2) may extend below tips of the array of active areas 215-1 through 215-n and/or the corrugated sidewall structure 235. Additionally, or alternatively, one or more of the array of conductive line structures 250-1 through 250-n may extend towards bases of the array of active areas 215-1 through 215-n and/or the corrugated sidewall structure 235 Additionally, or alternatively, one or more of the array of active areas 215-1 through 215-n and/or the corrugated sidewall structure 235 may penetrate into the array of conductive line structures 250-1 through 250-n through undersides of the array of conductive line structures 250-1 through 250-n.

As shown in FIG. 2, the approximately linear sidewall structure 230 may be approximately parallel to the array of conductive line structures 250-1 through 250-n. Additionally, or alternatively, the corrugated sidewall structure 235 may be approximately orthogonal to the array of conductive line structure 250-1 through 250-n. Additionally, or alternatively, each segment of the series of segments 240-1 through 240-n may be approximately parallel to the array of conductive line structures 250-1 through 250-n.

As indicated above, FIG. 2 is provided as an example. Other examples may differ from what is described with regard to FIG. 2.

As described in connection with FIGS. 1 and 2, and in some implementations, an integrated assembly includes an array of semiconductive fin structures (e.g., the array of active areas 215-1 through 215-n) penetrating through a dielectric region (e.g., the dielectric region 220). The integrated assembly includes a semiconductive moat structure (e.g., the moat structure 225) along the dielectric region that includes a sidewall structure (e.g., the corrugated sidewall structure 235). The sidewall structure includes first segments (e.g., the segments 240-1 and 240-n) that are biased inwardly toward the array of semiconductive fin structures and second segments (e.g., the segment(s) 240-2) that are biased outwardly away from the array of semiconductive fin structures, where the first segments and second segments alternate along an edge of the dielectric region. The integrated assembly includes an array of conductive line structures (e.g., the array of conductive line structures 250-1 through 250-n) that extend across the array of semiconductive fin structures, across the dielectric region, and across the sidewall structure.

Additionally, or alternatively and in some implementations, an apparatus includes a memory device (e.g., the memory array 205) that includes a word line structure (e.g., a conductive line structure of the array of conductive line structures 250-1 through 250-n) that is along a first axis (e.g., the x-axis). The memory device further includes and a corrugated sidewall structure (e.g., the corrugated sidewall structure 235) that extends along a second axis (e.g., the z-axis) that is approximately orthogonal to the first axis. In some implementations, a portion of the corrugated sidewall structure penetrates into the word line structure from an underside of the word line structure.

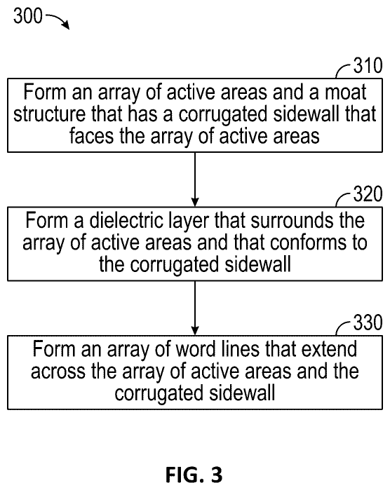

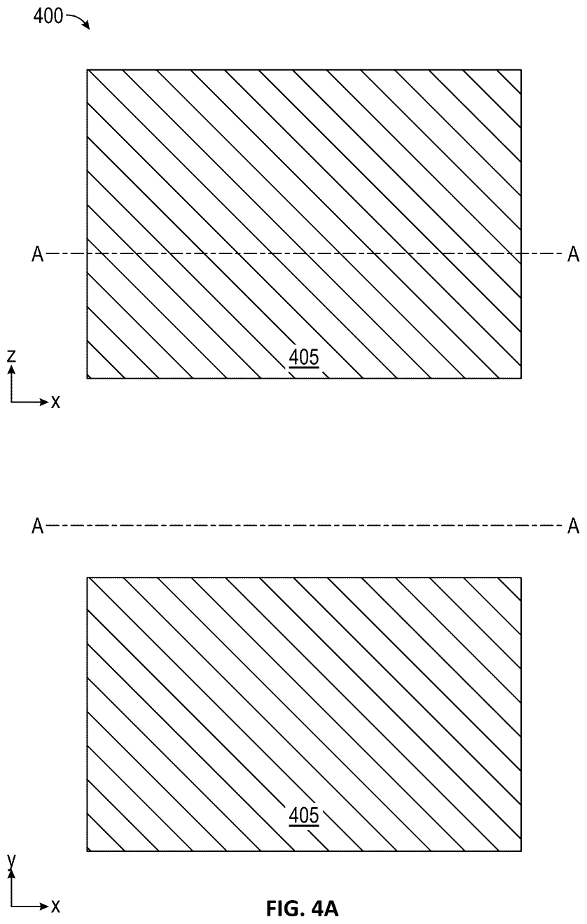

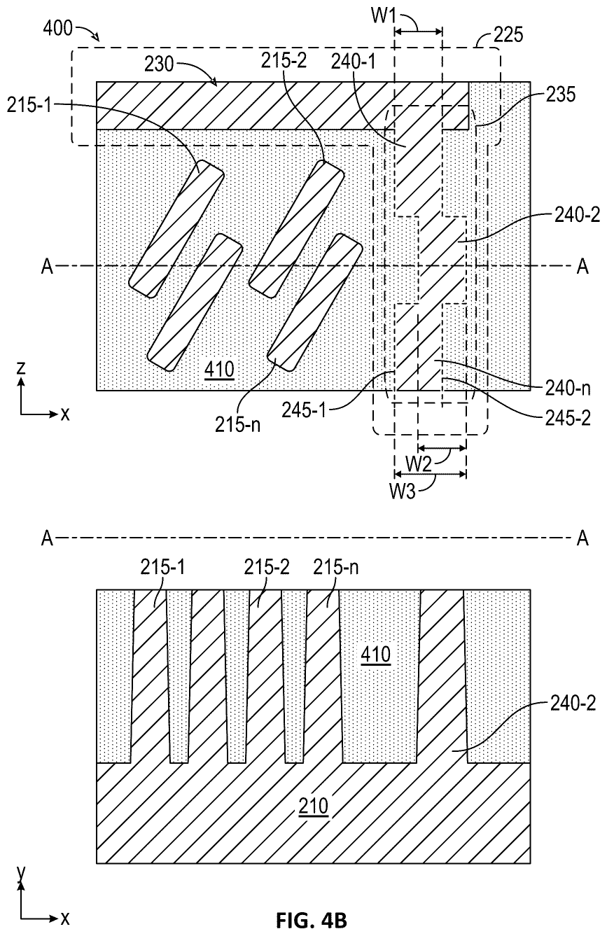

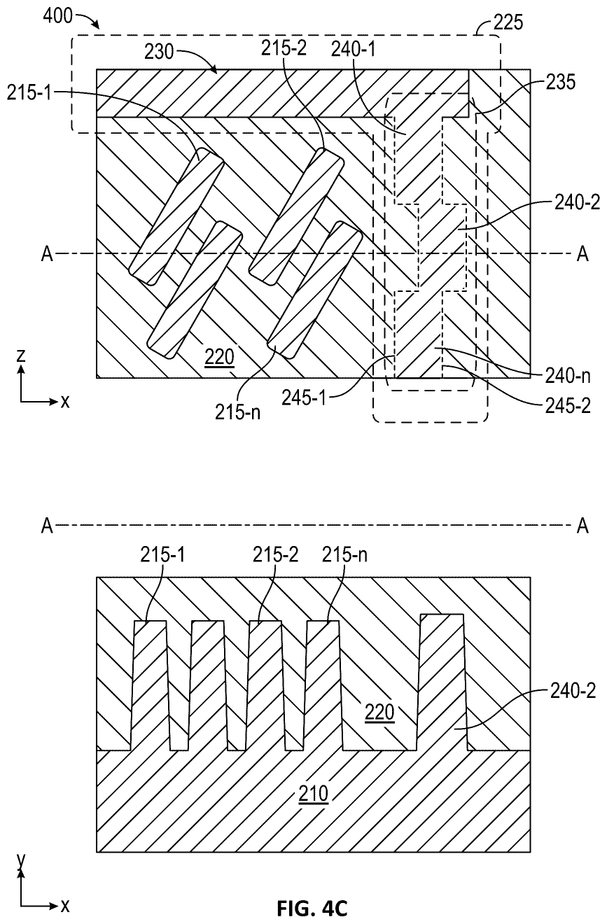

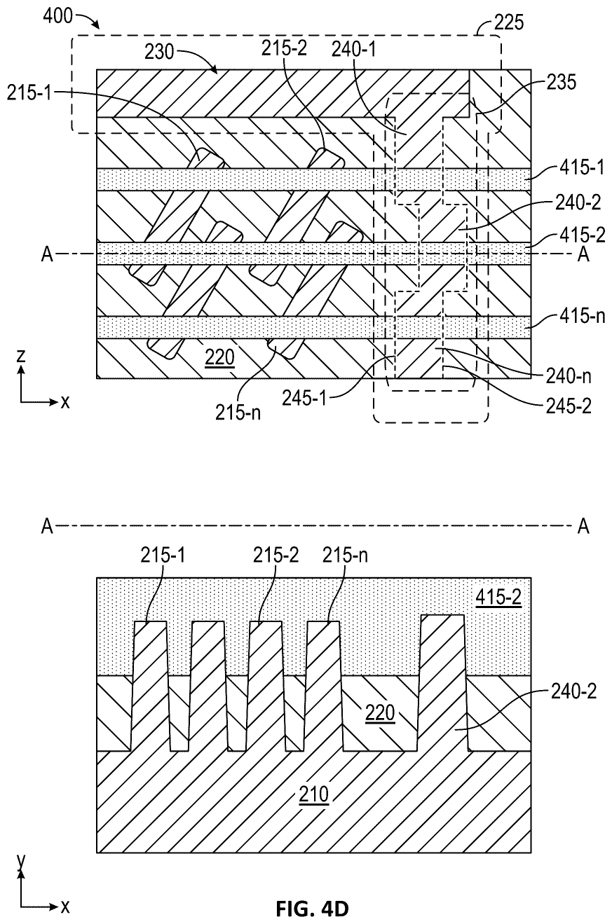

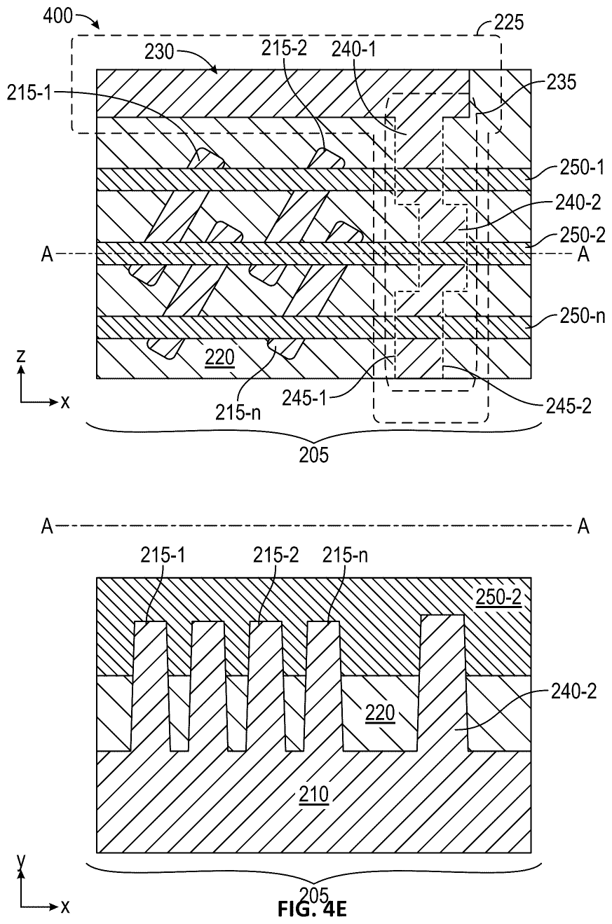

In these ways, and as described in greater detail in connection with FIGS. 3-4E, the integrated assembly and/or the apparatus may be formed with a reduced risk of open failures in the array of conductive line structures and increased structural integrity, thereby improving a quality and/or a reliability of the integrated assembly and/or the apparatus. The reduced risk of open failures and the increased structural integrity may improve technical and resource efficiencies by reducing the amount of resources (e.g., raw materials, labor, semiconductor manufacturing equipment, and/or computing resources) needed to support the market consuming the integrated assembly and/or the apparatus.

FIG. 3 is a flowchart of an example method 300 of forming an integrated assembly or memory device having with a corrugated sidewall structure (e.g., the corrugated sidewall structure 235). In some implementations, and as described in greater detail in connection with FIGS. 4A-4E, one or more process blocks of FIG. 3 may be performed by various semiconductor manufacturing equipment.

As shown in FIG. 3, the method 300 may include forming an array of active areas (e.g., the array of active areas 215-1 through 215-n) and a moat structure (e.g., the moat structure 225) that has a corrugated sidewall (e.g., the corrugated sidewall structure 235) that faces the array of active areas (block 310). As further shown in FIG. 3, the method 300 may include forming a dielectric region (e.g., the dielectric region 220) that surrounds the array of active areas and that conforms to the corrugated sidewall (block 320). As further shown in FIG. 3, the method 300 may include forming an array of word lines (e.g., the array of conductive line structures 250-1 through 250-n) that extend across the array of active areas and the corrugated sidewall (block 330).

The method 300 may include additional aspects, such as any single aspect or any combination of aspects described below and/or in connection with one or more other methods described elsewhere herein.

In a first aspect, forming the moat structure includes forming, over a layer of a semiconductive material, a hard mask pattern having an opening with a crenellated profile, and removing a portion of the semiconductive material through the opening as part of forming the corrugated sidewall.

In a second aspect, alone or in combination with the first aspect, forming the moat structure includes forming, over a layer of a semiconductive material, a photoresist pattern having an opening with a crenellated profile, and removing a portion of the semiconductive material through the opening as part of forming the corrugated sidewall.

In a third aspect, alone or in combination with one or more of the first and second aspects, forming the dielectric layer includes forming, over the corrugated sidewall, a hard mask pattern having a segment with a crenellated profile, and forming the dielectric layer that conforms to the corrugated sidewall based on the segment.

In a fourth aspect, alone or in combination with one or more of the first through third aspects, forming the dielectric layer includes forming, over the corrugated sidewall, a photoresist pattern having alternating segments that form a crenellated profile, and forming the dielectric layer that conforms to the corrugated sidewall based on the photoresist pattern.

In a fifth aspect, alone or in combination with one or more of the first through fourth aspects, forming the array of word lines includes forming word lines that extend below tips of the active areas and the corrugated sidewall and toward bases of the active areas and the corrugated sidewall.

In a sixth aspect, alone or in combination with one or more of the first through fifth aspects, forming the array of word lines includes forming an array of trenches that extend across the array of active areas and the corrugated sidewall, and forming the array of word lines in the trenches.

In a seventh aspect, alone or in combination with one or more of the first through sixth aspects, forming the array of trenches includes forming the trenches using an etching process that removes portions of the dielectric layer, portions of the active areas, and portions of the corrugated sidewall.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the corrugated sidewall structure 235, an integrated assembly that includes the corrugated sidewall structure 235, any part described herein of the corrugated sidewall structure 235, and/or any part described herein of an integrated assembly that includes the corrugated sidewall structure 235. For example, the method 300 may include forming one or more of the parts of the memory cell 100, the memory array 205, and/or the moat structure 225.

FIGS. 4A through 4E are diagrammatic views showing formation of the corrugated sidewall structure 235 at stages of an example process 400 of forming the corrugated sidewall structure 235. In some implementations, the example process described below in connection with FIGS. 4A through 4E may correspond to the method 300 and/or one or more blocks of the method 300. However, the process described below is an example, and other example processes may be used to form the corrugated sidewall structure 235, an integrated assembly that includes the corrugated sidewall structure 235, and/or one or more parts of the corrugated sidewall structure 235 and/or the integrated assembly.

As shown in FIG. 4A, the process 400 may include forming (e.g., depositing or growing) a semiconductive layer 405. The semiconductive layer 405 may comprise, consist of, or consist essentially of silicon (e.g., polycrystalline silicon). Alternatively, the semiconductive layer 405 may comprise, consist of, or consist essentially of a type III-V element (boron, aluminum, phosphorous, gallium arsenide, or gallium nitride, among other examples). In some implementations, a deposition tool may be used as part of forming the semiconductive layer 405 over and/or on a substrate, a semiconductive wafer, or a carrier using epitaxial growth, chemical vapor deposition, atomic layer deposition, physical vapor deposition, or another deposition technique.

As shown in FIG. 4B, the process 400 may include removing (e.g., etching) a portion of the semiconductive layer 405 to form a cavity complex 410 that reveals the semiconductive base 210, the array of active areas 215-1 through 215-n, and the moat structure 225 having the corrugated sidewall structure 235. In some implementations, a mask pattern may be used as part of forming the cavity complex 410. For example, a mask pattern having an opening with a crenellated profile may be formed over and/or on the semiconductive layer 405 prior to removing the portion of the semiconductive layer 405 to form the cavity complex 410 and reveal the semiconductive base 210, the array of active areas 215-1 through 215-n, and the moat structure 225 having the corrugated sidewall structure 235.

In some implementations, forming the mask pattern includes a set of lithography tools (e.g., a coating tool, an exposure tool, and a developer tool) forming a photoresist pattern. In some implementations, forming the mask patten includes a deposition tool, a set of lithography tools, and an etch tool forming a hard mask pattern (e.g., an oxide pattern or a nitride pattern). In some implementations, an etch tool may be used as part of removing the portion of the semiconductive layer through the opening in the mask pattern using a wet etch, a dry etch, or another suitable etch technique, among other examples.

In some implementations, forming the corrugated sidewall structure 235 includes forming an inwardly-biased segment (e.g., the segment 240-1) to have a width W1 and an outwardly-biased segment (e.g., the segment 240-2) to have a width W2. In some implementations, the width W1 and the width W2 are a same approximate width. Additionally, or alternatively, forming the corrugated sidewall structure 235 includes forming the corrugated sidewall structure 235 to have an overall width W3, where the overall width W3 is greater than the width W1 and/or the width W2.

In some implementations, a ratio of the width W3 to the width W1 (e.g., W3:W1) is greater than approximately 5:2 (e.g., approximately 2.5). If the ratio W3:W1 is less than approximately 5:2, a structural integrity of the corrugated sidewall structure 235 may be reduced and a risk of toppling and/or collapsing during subsequent manufacturing operations may be increased. Additionally, or alternatively, an amount of semiconductive material included in the segment 240-1 (e.g., and other inwardly-biased segments) may cause a substantial difference in etch rates across the array of active areas 215-1 through 215-n and the corrugated sidewall structure 235. As described in greater detail in connection with FIG. 4D, a substantial difference in the etch rates may cause an uneven formation of trenches used to form a conductive line structures (e.g., the array of conductive line structures 250-1 through 250-n) across the array of active areas 215-1 through 215-n and across the corrugated sidewall structure 235, thereby increasing a likelihood of defects in the array of conductive line structures. However, other values and/or ranges for the ratio W3:W1 are within the scope of the present disclosure.

In some implementations, a ratio of the width W3 to the width W2 (e.g., W3:W2) is greater than approximately 5:2 (e.g., approximately 2.5). If the ratio W3:W2 is less than approximately 5:2, a structural integrity of the corrugated sidewall structure 235 may be reduced to increase a risk of toppling and/or collapsing during subsequent manufacturing operations. Additionally, or alternatively, an amount of semiconductive material included in the segment 240-2 (e.g., and other outwardly-biased segments) may cause a substantial difference in etch rates across the array of active areas 215-1 through 215-n and the corrugated sidewall structure 235 As described in greater detail in connection with FIG. 4D, a substantial difference in the etch rates may cause an uneven formation of trenches used to form an array of conductive line structures (e.g., the array of conductive line structures 250-1 through 250-n) across the array of active areas 215-1 through 215-n and the segment 240-2, thereby increasing a likelihood of defects in the array of conductive line structures. However, other values and/or ranges for the ratio W3:W2 are within the scope of the present disclosure.

As shown in FIG. 4C, the process 400 may include forming (e.g., depositing or growing) the dielectric region 420. The dielectric region 220 may comprise, consist of, or consist essentially of one or more layers of silicon dioxide, among other examples. Forming the dielectric region 220 may include forming portions that surround the array of active areas 215-1 through 215-n. Additionally, or alternatively, forming the dielectric region 220 may include forming portions between the array of active areas 215-1 through 215-n and the corrugated sidewall structure 235. Additionally, or alternatively, forming the dielectric region 220 may include forming portions along surfaces of the corrugated sidewall structure 235 corresponding to the crenellated profile 245-1 and/or the crenellated profile 245-2. In some implementations, a deposition tool may be used as part of forming the dielectric region 220 using chemical vapor deposition, atomic layer deposition, physical vapor deposition, or another deposition technique, among other examples.

As shown in FIG. 4D, the process 400 may include forming an array of trenches 415-1 through 415-n across the array of active areas 215-1 through 215-n, the dielectric region 220, and across the corrugated sidewall structure 235. Forming the array of trenches 415-1 through 415-n may include removing (e.g., etching) portions the array of active areas 215-1 through 215-n, the dielectric region 220, and the corrugated sidewall structure 235. In some implementations, an etch tool may be used as part of removing portions the array of active areas 215-1 through 215-n, the dielectric region 220, and the corrugated sidewall structure 235 using a wet etch, a dry etch, or another suitable etch technique, among other examples.

Based on widths of the corrugated sidewall structure 235 as described in connection with FIG. 4B, etch rates of the portions of the array of active areas 215-1 through 215-n and the corrugated sidewall structure 235 may be substantially similar, resulting in the array of trenches 415-1 through 415-n to have substantially uniform depth across the array of active areas 215-1 through 215-n and the corrugated sidewall structure 235. Additionally, or alternatively and as shown in the side view of FIG. 4D, heights of the array of active areas 215-1 through 215-n and the corrugated sidewall structure 235 (e.g., the segment 240-2) may be substantially similar. Based on the substantially uniform depth and/or the substantially similar heights, an array of conductive line structures (e.g., the array of conductive line structures 250-1 through 250-n) may be formed across the array of active areas 215-1 through 215-n and the corrugated sidewall structure 235 with a reduced likelihood of defects.

As shown in FIG. 4E, the process 400 may include forming (e.g., depositing or growing) the array of conductive line structures 250-1 through 250-n (e.g., an array of word lines) in the array of trenches 415-1 through 415-n. The array of conductive line structures 250-1 through 250-n may include a conductive material. The conductive material may be an electrical conductor and may comprise, consist of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), among other examples. In some implementations, a deposition tool may be used as part of forming the array of conductive line structures 250-1 through 250-n using chemical vapor deposition, atomic layer deposition, physical vapor deposition, electroplating, or another deposition technique.

As indicated above, the process steps described in connection with FIGS. 4A through 4E are provided as examples. Other examples may differ from what is described with respect to FIGS. 4A through 4E. The structure shown in FIG. 4E may be equivalent to the memory array 205 including the moat structure 225 having the corrugated sidewall structure 235 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

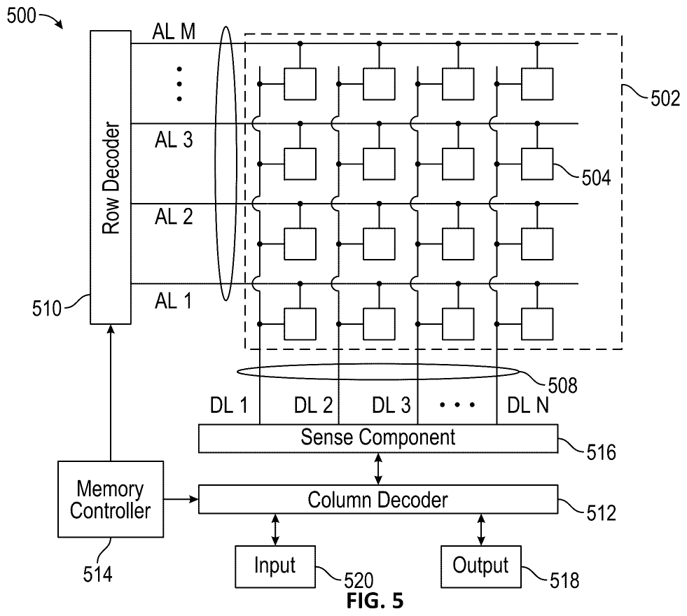

FIG. 5 is a diagrammatic view of an example memory device 500. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes the moat structure 225 having the corrugated sidewall structure 235, and/or an integrated assembly that includes the moat structure 225 having the corrugated sidewall structure 235. For example, the memory array 502 may include the moat structure 225 having the corrugated sidewall structure 235, and/or an integrated assembly that includes the moat structure 225 having the corrugated sidewall structure 235. Additionally, or alternatively, the memory cell 504 may include a memory cell described elsewhere herein.

As indicated above, FIG. 5 is provided as an example. Other examples may differ from what is described with respect to FIG. 5.

In some implementations, an integrated assembly includes an array of semiconductive fin structures penetrating through a dielectric region; a semiconductive moat structure along the dielectric region, comprising: a sidewall structure, comprising: first segments that are biased inwardly toward the array of semiconductive fin structures; and second segments that are biased outwardly away from the array of semiconductive fin structures, wherein the first segments and second segments alternate along an edge of the dielectric region; and an array of conductive line structures that extend across the array of semiconductive fin structures and across the dielectric region, wherein the array of conductive line structures extend across the sidewall structure.

In some implementations, an apparatus includes a memory device including a word line structure that is along a first axis and a corrugated sidewall structure that extends along a second axis that is approximately orthogonal to the first axis. In some implementations, a portion of the corrugated sidewall structure penetrates into the word line structure from an underside of the word line structure.

In some implementations, a method includes forming an array of active areas and a moat structure that has a corrugated sidewall that faces the array of active areas; forming a dielectric region that surrounds the array of active areas and that conforms to the corrugated sidewall; and forming an array of word lines that extend across the array of active areas and the corrugated sidewall.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for case of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise. As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
an array of semiconductive fin structures penetrating through a dielectric region;
a semiconductive moat structure along the dielectric region, comprising:
a sidewall structure, comprising:
first segments that are biased inwardly toward the array of semiconductive fin structures; and
second segments that are biased outwardly away from the array of semiconductive fin structures,
wherein the first segments and second segments alternate along an edge of the dielectric region; and
an array of conductive line structures that extend across the array of semiconductive fin structures and across the dielectric region,
wherein the array of conductive line structures extend across the sidewall structure.

2. The integrated assembly of claim 1, wherein each of the first segments and each of the second segments has a same approximate width.

3. The integrated assembly of claim 1, wherein each of the first segments and each of the second segments is approximately orthogonal to the array of conductive line structures.

4. The integrated assembly of claim 1, wherein the semiconductive moat structure further comprises:
another sidewall structure that is approximately parallel to the array of conductive line structures and that joins with the sidewall structure.

5. The integrated assembly of claim 1, wherein the array of semiconductive fin structures and the semiconductive moat structure comprise silicon.

6. The integrated assembly of claim 1, wherein the array of semiconductive fin structures and the semiconductive moat structure comprise a type III-V element.

7. An apparatus, comprising:
a memory device, comprising:
a word line structure that is along a first axis; and
a corrugated sidewall structure that extends along a second axis that is approximately orthogonal to the first axis,
wherein a portion of the corrugated sidewall structure penetrates into the word line structure from an underside of the word line structure.

8. The apparatus of claim 7, further comprising:
an active area that is adjacent to the corrugated sidewall structure and that penetrates into the word line structure from the underside of the word line structure.

9. The apparatus of claim 8, further comprising:
a dielectric region between the active area and the corrugated sidewall structure.

10. The apparatus of claim 9, wherein surfaces of the dielectric region conjoin with surfaces of the active area and surfaces of the corrugated sidewall structure.

11. The apparatus of claim 9, wherein a surface of the corrugated sidewall structure facing the dielectric region comprises:
a serpentine profile.

12. The apparatus of claim 11, wherein the serpentine profile is a first serpentine profile, and wherein a surface of the corrugated sidewall structure facing away from the dielectric region comprises:
a second serpentine profile that is approximately parallel to the first serpentine profile.

13. A method, comprising:
forming an array of active areas and a moat structure that has a corrugated sidewall that faces the array of active areas;
forming a dielectric layer that surrounds the array of active areas and that conforms to the corrugated sidewall; and
forming an array of word lines that extend across the array of active areas and the corrugated sidewall.

14. The method of claim 13, wherein forming the moat structure includes:
forming, over a layer of a semiconductive material, a hard mask pattern having an opening with a crenellated profile, and
removing a portion of the semiconductive material through the opening as part of forming the corrugated sidewall.

15. The method of claim 13, wherein forming the moat structure includes:
forming, over a layer of a semiconductive material, a photoresist pattern having an opening with a crenellated profile, and
removing a portion of the semiconductive material through the opening as part of forming the corrugated sidewall.

16. The method of claim 13, wherein forming the dielectric layer includes:
forming, over the corrugated sidewall, a hard mask pattern having a segment with a crenellated profile; and
forming the dielectric layer that conforms to the corrugated sidewall based on the segment.

17. The method of claim 13, wherein forming the dielectric layer includes
forming, over the corrugated sidewall, a photoresist pattern having alternating segments that form a crenellated profile; and
forming the dielectric layer that conforms to the corrugated sidewall based on the photoresist pattern.

18. The method of claim 13, wherein forming the array of word lines includes:
forming word lines that extend below tips of the active areas and the corrugated sidewall and toward bases of the active areas and the corrugated sidewall.

19. The method of claim 13, wherein forming the array of word lines includes:
forming an array of trenches that extend across the array of active areas and the corrugated sidewall, and
forming the array of word lines in the trenches.

20. The method of claim 19, wherein forming the array of trenches includes:
forming the trenches using an etching process that removes portions of the dielectric layer, portions of the active areas, and portions of the corrugated sidewall.
